(19) United States
(12) Patent Application Publication
(10) Pub. No.: US 2019/0056668 A1
(43) Pub. Date: Feb. 21, 2019

(54) STRIPPING SOLVENTS FOR PHOTOSENSITIVE RESINS

(71) Applicant: RHODIA OPERATIONS, Paris (FR)

(72) Inventor: Arnaud BOURDETTE, Chelles (FR)

(21) Appl. No.: 15/760,436

(22) PCT Filed: Sep. 14, 2016
(86) PCT No.: PCT/EP2016/071695

§ 371 Date: Mar. 15, 2018

(30) Foreign Application Priority Data
Sep. 17, 2015 (FR) 15 58739

(51) Int. Cl. G03F 7/32

(52) U.S. Cl. CPC G03F 7/325

(57) ABSTRACT

The present invention relates to the use, as photoresist-stripping solvent, of a mixture of solvents comprising at least two of the following solvents.
(S1) a solvent comprising at least one esteramide compound of formula R¹OOC-A-CONR²R³
(S2) DMSO
(S3) cyclopentanone.

The present invention relates to the field of the stripping of photoresists used in photolithography processes.

Photoresists (also known as photoresins or photosensitive resins) are well-known materials, the properties of which differ before and after exposure to suitable irradiation. This irradiation is typically an electromagnetic radiation, for example a UV radiation with a wavelength of between 300 and 450 nm for photoresins of DNQ (diazonaphthoquinone) type, or, more rarely, an electron beam for more specific resins (in the broad sense, resins of this type will be considered herein to be “photosensitive” even if light radiation is not involved).

Typically, the irradiation modifies the solubility of the photoresist in a solvent termed “developer” solvent. In this context, there are two types of photoresists, namely:

“positive” photoresists:

before exposure, these resins are insoluble (or else very slowly soluble) in the developer solvent. Conversely, after exposure, they become soluble (or at least much more rapidly soluble, with typically a dissolution rate of the film multiplied at least by a factor of 100); and

“negative” photoresists:

before exposure, these resins art soluble in the developer solvent and, after irradiation, they become insoluble (or at least much more slowly soluble, with typically a dissolution rate of the film reduced by at least a factor of 100).

Photoresists make it possible in particular to form openwork coatings on the surface of a substrate, and this is used in many industrial processes, including in particular photolithography which allows the preparation of microelectronic components (chips, diodes, transistors, screens, etc.).

According to one method known per se, a photoresist used in photolithography is typically deposited in the form of a thin film on the surface of a substrate (silicon or silicon oxide for example) and then it is exposed, only on certain zones, to the radiation that induces its solubility modification. The selective irradiation then modifies the resin only where it has been exposed, thus forming two types of zone on the surface, namely “soluble” zones, which can be removed with the developer solvent, and “insoluble” zones which cannot be removed by the developer solvent or else are more difficult for the developer solvent to remove, Through the action of the developer solvent, the soluble zones are then removed in a step that will be denoted in the present description as “stripping the photoresist”,

With a positive photoresist, the step of “stripping the photoresist” with the developer solvent in fact makes it possible to remove the resin that has been photosensitized (irradiated).

In the case of a negative photoresist, the step of stripping the photoresist makes it possible, conversely, to remove the resin that has not been photosensitized (irradiated).

The stripping of the photoresist leaves behind a film deposited on the surface in a pattern which masks only the non-irradiated zones in the case of a positive resin and which masks only the irradiated zones in the case of a negative resin. (In practice, the surface to be treated is irradiated through an openwork mask. The use of positive resin makes it possible, after irradiation and action of the solvent, to reproduce on the surface a film of protective resin which is the exact image of the mask. The negative resin, conversely, forms on the surface a negative of the mask). This selective masking allows selective protection of the surface, which typically makes it possible to etch the unprotected zones while leaving intact those located under the film.

The present invention is concerned with a new type of developer solvent suitable for performing a stripping of photoresist of the abovementioned type.

At the current time, photoresist stripping is usually carried out by means of N-methylpyrrolidone (1-methyl-2-pyrrolidone, hereinafter referred to as “NMP”).

NMP is known to be effective for stripping numerous photoresists normally used in photolithography. NMP is also a powerful solvent which makes it possible to keep the resin dissolved in solution and to remove the organic impurities.

However, a problem with NMP lies in its toxicity. In Europe, for example, this solvent is on the SVHC (for “Substances of Very High Concern”) list of the European Chemicals Agency (ECHA) and is classified as a dangerous chemical agent CMR 1B, corresponding to a substance that is toxic to reproduction.

An objective of the present invention is to provide an efficient means for carrying out photoresist stripping which does not exhibit the same toxicity problems as NMP. In other words, the invention aims to provide a developer which is a non-toxic alternative to NMP and which makes it possible to strip most, if not all, of the photoresists that can be used with NMP.

To this effect, the present invention proposes to carry out the stripping by means of a specific mixture of solvents, which the inventors have now demonstrated provides efficient stripping of photoresists, in particular most of the photoresists that NMP makes it possible to strip.

More specifically, according to a first aspect, a subject of the present invention is the use, for stripping a photoresist, of a mixture of solvents comprising at least two, or even three, of the solvents (S1), (S2) and (S3) below:
(S1) a solvent comprising at least one esteramide compound corresponding to formula (I) below:

R¹OOC-A-CONR²R³ (I)

wherein:
R¹ is a group selected from saturated or unsaturated, linear or branched, optionally cyclic, optionally aromatic, hydrocarbon-based groups comprising an average number of carbon atoms ranging from 1 to 36,
R² and R³, which may be identical or different, are groups selected from saturated or unsaturated, linear or branched, optionally cyclic, optionally aromatic, optionally substituted, hydrocarbon-based groups comprising an average number of carbon atoms ranging from 1 to 36, R² and R³ together optionally being able to form a ring, which is optionally substituted and/or optionally comprises a heteroatom, and
A is a linear or branched divalent alkyl group comprising an average number of carbon atoms ranging from 2 to 12, preferably from 2 to 4
(S2) dimethyl sulfoxide DMSO
(S3) cyclopentanone C₅H₈O.

The notion of “average number” of carbon atoms, in the sense in which it is used herein, is understood in its most common definition. Thus, for a solvent (S1) containing a single compound of formula (I), the “average number” of carbon atoms in the R¹, R², R³ and A groups is strictly equal to the number of carbon in each of these groups. In some situations, the solvent (S1) can contain several compounds of formula (I) which can differ from one another by their R¹ and/or R² and/or R³ and/or A groups. In this case, the average number of carbon atoms in each group is typically defined by the number average denoted N of the number of carbon atoms in a given group in the total population of compounds of formula (I). By way of example, the average number of carbon atoms N(R¹) in the R¹ group for a population of compounds of formula (I) which exhibit distinct R¹ groups can be calculated as follows:

N(R¹)=Σᵢ₌ₗₘᵢₙ^{lmax}iNi/Σᵢ₌ₗₘᵢₙ^{lmax}Ni

wherein:
lmin and Imax are two integers, equal respectively to the minimum number and to the maximum number of carbon atoms in the R¹ groups of the compounds of the population in question; and
for each value of i ranging from lmin to lmax, Ni is an integer equal to the number of compounds of the population wherein the R¹ group comprises exactly i carbon atoms.

According to another aspect, a subject of the invention is a process for selective depositing of a coating on certain zones only of the surface of a substrate, comprising (a) depositing of a film of photoresist on said surface; then (b) selective irradiation of said film on certain zones only; then (e) stripping of said film with a stripping solvent, wherein said stripping solvent is a solvent of the abovementioned type.

The process of the invention can in particular be used in photolithography, in particular for the fabrication of a printed circuit, of a microelectronics component or of a screen.

The studies carried out in the context of the present invention have now made it possible to show that the mixture of the abovementioned type allow acceptable stripping, and in some cases very efficient stripping, of photoresists, and in particular those conventionally stripped using NMP.

In addition, the mixtures of solvent according to the invention have the advantage of being water-soluble, which allows simple and efficient rinsing after the stripping, by simply washing with water.

According to a first possible embodiment of the present invention, the mixture of solvents used comprises (or even consists of) the solvent (S1) and the solvent (S2).

In this embodiment, the S1/S2 weight ratio of the weight of the solvent (S1) relative to the weight of the solvent (S2) is preferably between 0.1 and 10. For example, use may be made, according to this embodiment, of mixtures comprising the solvents (S1) and (S2) in the following respective weight proportions: 10;90; 20:80; 30:70; 40:60; 50:50; 60:40; 70:30; 80:20 or 90:10.

For the purposes of the present description, “a mixture comprising the solvents (S1) and (S2) in the respective weight proportions 10:90” denotes a mixture of solvents including, among other possible solvents, the solvents (S1) and (82), and wherein the ratio of the weight of the solvent (S1) to the total of the weights of the solvents (S1) and (S2) is 10% (the ratio of the weight of the solvent (S2) relative to the total of the weights of the solvents (S1) and (S2) itself being 90%),

According to this first embodiment, the (S1)/(S2) weight ratio is preferably as high as possible, for example greater than or equal to 1. This is because DMSO has a quite unpleasant particular odor and it is often preferred to reduce the content thereof. In particular for this reason, use may preferably be made of the mixtures comprising the solvents (S1) and (S2) in the following respective weight proportions: 50:50; 60:40; 70:30; 80:20 or 90:10.

However, the inventors have observed that the mixtures according to this first embodiment tend to exhibit a better stripping efficiency when the DMSO content increases. From this point of view, mixtures wherein the (S1)/(S2) ratio is lower, for example less than or equal to 1, prove to be advantageous. In particular for this reason, use may therefore preferably be made of the mixtures comprising the solvents (S1) and (S2) in the following respective weight proportions: 10:90; 20:80; 30:70; 40:60; 50:50.

According to a first possible variant of this first embodiment, the mixture of solvents used according to the invention consists only of the solvents (S1) and (S2), advantageously in the abovementioned proportions.

By way of example, an advantageous mixture of solvents according to the invention consists of the solvents (S1) and (S2) in weight proportions of between 40:60 and 60:40, in particular in the weight proportions 50:50.

Another example of an advantageous mixture of solvents according to the invention consists of the solvents (S1) and (S2) in weight proportions of between 20:80 and 40:60, in particular in the weight proportions 30:70.

Yet another example of an advantageous mixture of solvents according to the invention consists of the solvents (S1) and (82) in weight proportions of between 5:85 and 20:80, in particular in the weight proportions 10:90.

According to a second possible variant of the first embodiment, the mixture of solvents used according to the invention can comprise one or more other solvents in addition to the solvents (S1) and (S2), and in particular the solvent (S3).

According to one particular variant, the mixture of solvents according to the invention comprises the solvents (S1), (S2) and (S3). The mixture of solvents according to the invention may typically consist only of the solvents (S1), (S2) and (S3).

When the mixture of solvents according to the invention comprises the solvents (S1), (S2) and (S3), the S3/(S1+S2) weight ratio of the weight of the solvent (S3) to the total of the weights of the other solvents is preferably less than 50%, usually less than 25%, or even less than 15%. The presence of the solvent. S3 induces in general a decrease in the flashpoint of the solvent and it may therefore be advantageous to reduce the content thereof when seeking to obtain a high flashpoint.

Usually, whether the solvents S1 and S2 are present together or not, it is preferable, in a mixture according to the invention, for the S3/(S1+S2) weight ratio to be less than 10%, for example between 2% and 7% typically about 5%.

By way of example, an advantageous mixture of solvents according to the invention consists of the solvents (S1), (S2) and (S2) in the weight proportions 35:60:5.

Another typical example of an advantageous mixture of solvents according to the invention consists of the solvents (S1) and (S2) in the weight proportions 30:65:5.

Another typical example of an advantageous mixture of solvents according to the invention consists of the solvents (SI) and (S2) in the weight proportions 25:70:5.

Yet another example of an advantageous mixture of solvents according to the invention consists of the solvents (S1) and (S2) in the weight proportions 20:75:5.

Yet another example of an advantageous mixture of solvents according to the invention consists of the solvents (SI) and (S2) in the weight proportions 15:80:5,

Yet another example of an advantageous mixture of solvents according to the invention consists of the solvents (S1) and (S2) in the weight proportions 10:85:5.

Yet another example of an advantageous mixture of solvents according to the invention consists of the solvents (S1) and (S2) in the weight proportions 5:90.5.

According to a second possible embodiment of the present invention, the mixture of solvents used comprises (or even consists of) the solvent (S1) and the solvent (S3).

In this embodiment, the S1/S3 weight ratio of the weight of the solvent (S1) relative to the weight of the solvent (S3) is preferably between 0.1 and 100, and it is typically between 1 and 20. For example, use may be made, according to this embodiment, of mixtures comprising the solvents (S1) and (S3) in the following respective weight proportions: 50:50; 60:40; 70:30; 75:25; 80:20; 85:15; 90:10; or 95:5. When it is sought to obtain a high flashpoint, it is generally appropriate to limit the amount of solvent (S3). This is because, the higher its content, the more the flashpoint of the mixture tends to decrease. To this effect, use may be made of mixtures comprising the solvents (S1) and (S3) in weight proportions advantageously between 70:30 and 95:5.

According to one possible variant of this first embodiment, the mixture of solvents used according to the invention consists only of the solvents (S1) and (S3), advantageously in the abovementioned proportions. By way of example, an advantageous mixture of solvents according to the invention consists of the solvents (S1) and (S3) in weight proportions of between 80:20 and 95:5, in particular in the weight proportions of between 85:15 and 95:5, for example.

According to a third possible embodiment of the present invention, the mixture of solvents used comprises (or even consists of) the solvent (S2) and the solvent (S3).

In this embodiment, the S2/S3 weight ratio of the weight of the solvent (S2) relative to the weight of the solvent (S3) is preferably between 0.1 and 100, typically between 1 and 20. For example, use may be made, according to this embodiment, of mixtures comprising the solvents (S1) and (S2) in the following respective weight proportions: 50:50; 60:40; 70:30; 75:25; 80:20; 85:15; 90:10; or 95:5.

The (S2)/(S3) ratio is preferably as low as possible, if it is desired to decrease the odor associated with the presence of DMSO. In particular for this reason, use may preferably be made of the mixtures comprising the solvents (S1) and (S2) in the following respective weight proportions: 30:70; 40:60; 50:50; 60:40; or 70:30.

In terms of flashpoint, however, mixtures wherein the (S2)/(S3) ratio is higher often prove to be more advantageous. Furthermore, in particular for these reasons, use may therefore preferably be made of the mixtures comprising the solvents (S2) and (S3) in the following respective weight proportions: 75:25, 80:20; 85:15; 90:10; or 95:5.

According to one possible variant of this first embodiment, the mixture of solvents used according to the invention consists only of the solvents (S2) and (S3), advantageously in the abovementioned proportions.

By way of example, an advantageous mixture of solvents according to the invention consists of the solvents (S2) and (S3) in weight proportions of between 80:20 and 95:5, in particular in the weight proportions of between 85:15 and 95:5.

Various characteristics and preferential embodiments of the invention are described in detail below:

The Solvent (S1)

The solvent of (SI) type that is of use in the context of the present invention, and in particular for the abovementioned first and second embodiments, preferably comprises a mixture of compounds of formula (I) as defined above, wherein A, R¹, R² and R³ have the abovernentioned meanings. Thus, it may advantageously be the commercial solvent Rhodiasolv® Polarclean available from the company Solvay, which comprises such a mixture.

In the compositions of formula (I) that are of use according to the invention, the R¹, R² and R³ groups, which are identical or different, can in particular be groups selected from alkyl, aryl, alkaryl and arylalkyl groups, which are typically C₁-C₂ groups, or the phenyl group. The R² and R³ groups can optionally be substituted, in particular with hydroxyl groups.

The R¹ group can in particular be selected from methyl, ethyl, propyl, isopropyl, n butyl, isobutyl, n-pentyl, isopentyl, isoamyl, n-hexyl, cyclohexyl, 2-ethylbutyl, n-octyl, isooctyl, 2-ethylhexyl and tridecyl groups.

The R² and R³ groups, which may be identical or different, can in particular be selected from methyl, ethyl, propyl (n-propyl), isopropyl, n-butyl, isobutyl, n-pentyl, amyl, isoamyl, hexyl, cyclohexyl and hydroxyethyl groups. The R² and R³ groups can also be such that they form, together with the nitrogen atom, a morpholine, piperazine or piperidine group. According to particular embodiments, R²=R³=methyl, or R²=R³=ethyl, or R²=R³=hydroxyethyl.

According to one particular embodiment, if A comprises a group of formula —CH₂—CH₂— and/or of formula —CH₂—CH₂—CH₂—CH₂— and/or of formula —(CH₂)₈— which is linear, then it is a mixture of groups A. According to one particular embodiment, if A is linear, then it is a mixture of groups A, for example a mixture of two or three of the —CH₂—CH₂—(ethylene); —CH₂—CH₂—CH₂— (n-propylene); and —CH₂—CH₂—CH₂—CH₂— (n-butylene) groups.

According to one particular embodiment, the group A is a divalent linear alkyl group selected from groups having the following formulae: —CH₂—CH₂— (ethylene); —CH₂—CH₂—CH₂— (n-propylene); —CH₂—CH₂—CH₂—CH₂— (n-butylene), and mixtures thereof.

In one particular variant in this first embodiment, the compound (I) that is of use according to the invention is selected from the following compounds (wherein Me represents a methyl group):

MeOOC—CH₂—CH₂—CONMe₂

MeOOC—CH₂—CH₂—CH₂—CONMe₂

MeOOC—CH₂—CH₂—CH₂—CONMe₂,

as a mixture with

MeOOC—CH —CH₂—CH₂—CH₂—CONMe₂

and/or with

MeOOC—CH₂—CH₂—CONMe₂.

According to a second particular embodiment of the invention, the group A is a divalent branched alkylene group having one of the formulae (IIa), (IIb), (IIc), (IIIa) and (IIIb) below, or a mixture of at least two groups selected from the groups of formulae (IIa), (IIb) and (IIc) or from the groups of formulae (IIIa) and (IIIb), or a mixture of at least two groups, one selected from the groups of formulae (IIa), (IIb) and (IIc) and the others selected from the groups of formulae (IIIa) and (IIIb):

—(CHR⁷)_{y}—(CHR⁶)ₓ—(CHR⁷)_{z}—CH₂—CH₂— (IIa)

—CH₂—CH₂—(CHR⁷)_{z}—(CHR⁶)ₓ—(CHR⁷)_{y}— (IIb)

—(CHR⁷)_{z}—CH₂—(CHR⁹)ₓ—CH₂—(CHR⁷)_{y}— (IIc)

—(CHR⁷)_{y}—(CHR⁶)ₓ—(CHR⁷)_{z}—CH₂— (IIIa)

—CH₂—(CHR⁷)_{z}—(CHR⁶)ₓ—(CHR⁷)_{y}— (IIIb)

wherein:
x is an integer greater than 0,
y is an average integer greater than or equal to 0,
z is an average integer greater than or equal to 0,
R⁶, which may be identical or different at each occurrence, is a C₁-C₆, preferably C₁-C₄, alkyl group, and
R⁷, which may be identical or different at each occurrence, is a hydrogen atom or a C₁-C₆, preferably C₁-C₄, alkyl group.
In this second particular embodiment, the group A is preferably a group such that

y=z=0.

Preferably, in formula (IIa) and/or in formula (IIb):

−x=1; y=z=0: R⁶=methyl.

Preferably, in formula (IIIa) and/or in formula (IIIb):

−x=1; y=z=0; R⁶=ethyl,

In one particular variant of the second particular embodiment, the compound of formula (I) that is of use according to the invention is selected from the following compounds, and mixtures thereof:

MeOOC-A_{MG}-CONMe₂

MeOOC-A_{ES}-CONMe₂

PeOOC-A_{MG}-CONMe₂

PeOOC-A_{ES}-CONMe₂

CycloOOC-A_{MG}-CONMe₂

CycloOOC-A_{ES}-CONMe₂

EhOOC-A_{MG}-CONMe₂

EhOOC-A_{ES}-CONMe₂

PeOOC-A_{MG}-CONEt₂

PeOOC-A_{ES}-CONEt₂

CycloOOC-A_{MG}-CONEt₂

CycloOC-A_{ES}-CONEt₂

BuOOC-A_{MG}-CONEt₂

BuOOC-A_{ES}-CONEt₂

BuOOC-A_{MG}-CONMe₂

BuOOC-A_{ES}-CONMe₂

EtBuOOC-A_{MG}-CONMe₂

EtBuOOC-A_{ES}-CONMe₂

nHE-OOC-A_{MG}-CONMe₂

nHE-OOC-A_{ES}-CONMe₂

wherein:
Me represents a methyl group
A_{MG} represents an MGₐ group of formula —CH(CH₃)—CH₂—CH₂—; or an MG_{b} group of formula —CH₂—CH₂—CH(CH₃)—; or a mixture of the abovementioned MGₐ and MG_{b} groups
A_{ES} represents an ESₐ group of formula —CH(C₂H₅)—CH₂—; or an ES_{b} group of formula —CH₂—CH(C₂H₅)—; or a mixture of ESₐ and ES_{b} groups
Pe represents a pentyl group, preferably isopentyl group or isoamyl group
Cyclo represents a cyclohexyl group
Eh represents a 2-ethylhexyl group
Bu represents a butyl group, preferably n-butyl group or tert-butyl group
Et represents an ethyl group and EtBu represents an ethylbultyl group
nHE represents an n-hexyl group.

According to one advantageous embodiment, the compound of formula (I) used according to the invention has a melting point of less than or equal to 20° C., preferably less than or equal to 5° C., preferably less than or equal to 0° C.

The compounds of formula (I) that are of use according to the invention can be prepared by any method known per se. It is possible in particular to carry out a step of reacting an anhydride corresponding to formula (I′) below with an alcohol of formula R¹—OH and/or an amine of formula HNR²R³

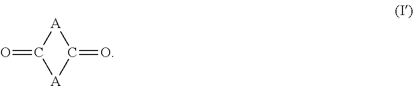

The anhydride may be prepared during a prior step a) of cyclizing a diacid of formula HOOC-A-COOH, preferably by reacting the diacid with acetic anhydride, It is in particular possible to carry out a reflux in an excess of acetic anhydride. A condensation of the product of formula (I′) can then be carried out.

One of the following reaction sequences 1) or 2) can in particular be carried out:

### Sequence 1):

Step 1b): the anhydride of formula (I′) is reacted with an alcohol of formula R¹—OH, so as to obtain an ester-acid compound of formula (I″) R¹—OOC-A-COOH,

Step 1c): the compound of formula (I″) is converted into a compound of formula (I) by means of an amine of formula HNR²R³,

### Sequence 2):

Step 2b): the anhydride of formula (I′) is reacted with an amine of formula HNR²R³ so as to obtain an amide-acid compound of formula (II″)

HOOC-A-CONR²R³ (II′),

Step 2c): the compound of formula (V) is converted into a compound of formula (I) by means of an alcohol of formula R¹—OH.

Step 1b) is preferably carried out by means of at least 1 molar equivalent of alcohol, relative to the anhydride. A strong excess of alcohol, for example from 2 to 20 equivalents, in particular from 5 to 15 equivalents, can be used. The alcohol can in particular be used as reaction solvent.

According to one particular embodiment, step 1c) comprises the following steps (which may be simultaneous or successive, preferably successive):

1c1) the compound of formula (I″) is converted to an acyl chloride of formula (I″′) below, preferably by reaction with thionyl chloride,

R¹-OOC-A-COCl (I′″)

1c2) the compound of formula (I″′) is reacted with the amine of formula HNR³R⁴ so as to obtain the compound of formula (I).

Step 1c2) is accompanied by formation of hydrochloric acid. A base can be used in order to trap it, for example triethanolamine or triethylarnine (TEA). This step can be carried out with at least 0.8 molar equivalent of amine, preferably with at least one equivalent. An excess of from 1.05 to 1.4 molar equivalents can in particular be used.

According to another process that is of use for preparing the compound of the invention, a step of reacting a diester of formula R¹OOC-A-COOR¹ with an amine of formula HNR²R³, then optionally a step of reaction with an alcohol of formula R^{1′}—OH, wherein R^{1′} is a group selected from the abovernentioned R groups, but different than the R¹ group of the diester, is carried out. This process is particularly advantageous and economical since the diesters are prepared in large amounts and are readily available. It is thus possible to optimize the production processes. The following reaction sequence 3) can for example be carried out:

### Sequence 3)

Step 3a): a diester of formula R¹OOC-A-COOR¹, preferably of formula MeOOC-A_{MG}-COOMe or MeOOC-A_{ES}-COOMe is reacted with an amine of formula HNR2R³ so as to obtain a product comprising an esteramide of formula:

R¹OOC-A-CONR²R³,

preferably R¹OOC-A_{MG}-CONR²R³ or R¹OOC-A_{ES}-CONR²R³, preferably MeOOC-A_{MG}-CONR²R³ or MeOOC-A_{ES}-CONR²R³

Step 3b); optionally, reaction is carried out with an alcohol of formula R^{1′}—OH so as to obtain a product comprising an esteramide of formula

R¹OOC-A-CONR²R³

preferably R^{1′}OOC-A_{MG}-CONR²R³ or R^{1′}OOC-A_{ES}-CONR²R³

wherein R¹′ is a group selected from the abovementioned R¹ groups, but different than the R¹ group of the theater.

If the starting diester exhibits the desired R¹ group of the compound, then step 3b) is generally needless. If not, this step will typically be carried out. Preferably, the diester exhibiting the desired R¹ group is used as starting point.

During step 3a), from 0.7 to 1.5, for example 0.8 to 1 2 mol, preferably from 0.9 to 1.1 mol, preferably approximately 1 mol of amine per mole of diester is preferably used. It is advantageous to operate with a slight excess, such as an excess of at least 1.05 mol of amine per mole of diester, for example from 1.05 to 1.1 mol of amine per mole of diester.

Step 3a) can be carried out in solution, for example in aqueous solution, or in solution in a solvent such as toluene or an alcohol. It is preferred to operate in a non-aqueous solution, while avoiding any presence of water. During this step, the methanol formed can be gradually removed in order to promote the reaction. The removal may be accompanied by removal of the solvent, for example with an azeotrope. After separation of the methanol, the solvent removed can be reintroduced into the process. Step 3a) is preferably carried out in the presence of a catalyst, in particular a catalyst of basic type. Methoxides such as MeONa, carbonates such as K₂CO₃ or Na₂CO₃, or titanates may for example be used.

Step 3b) is a trans-esterification step. It can in particular be catalyzed by acids or bases, for example by K₂CO₃, or Na₂CO₃.

It is noted that, in all the processes and sequences mentioned above, optional intermediate separation and/or purification steps can be carried out in order to remove unwanted by-products. The by-products can optionally be used to produce other products, or can be converted in order to be reintroduced into the process.

The reaction can be followed by steps of filtration and/or purification for example by distillation.

The diacids, where appropriate in the form of mixtures, can particularly be obtained from a mixture of dinitrile compounds, where appropriate in the form of mixtures. The dinitriles may in particular be dinitriles produced and recovered in the process for producing adiponitrile by double hydrogenation of butadiene. In this case, they may be mixtures of dinitriles, This process used on a large scale in industry to produce the vast majority of adiponitrile consumed throughout the world is described in numerous patents and books,

The butadiene hydrocyanation reaction results predominantly in the formation of linear dinitriles, but also in formation of branched dinitriles, the main two of which are methylglutaronitrile and ethylsuccinonitrile.

In the adiponitrile separation and purification steps, the branched dinitrile compounds are separated by distillation and recovered, for example, as a top fraction in a distillation column.

Diacids that are of use can be obtained by reaction between the dinitrile compounds and a mineral base, in order to obtain acid salts, followed by neutralization of these salts with an acid. Diacids that are of use can also be obtained by acid hydrolysis of the dinitrile compounds.

Diesters of formula R¹OOC-A-COOR¹ that are of use for carrying out the sequence 3 are commercially available, in particular from the company Invista under the references DBE, or from the company Solvay under the name Rhodiasolv® RPDE.

Processes for preparing diacids and/or diesters are in particular described in documents WO2007/101929, FR 2902095, WO 2008/009792 and WO 2008/062058.

The Solvents (S2) and (S3)

Theoretically, there is no limitation with regard to the exact nature of the DMSO and of the cyclopentanone that are used according to the invention.

Nevertheless, it may be advantageous to use mixtures comprising, as solvent (S2), DMSO in purified form, having a less strong odor. DMSO obtained according to the process described in patent U.S. Pat. No. 8,076,519 can for example be used.

An example of implementation of the invention is given below by way of illustration:

### EXAMPLE

A mixture according to the invention comprising the following was tested:
50% by weight of Rhodiasolv Polarclean®
   (Solvent of type (S1)—commercial product as available from the company Solvay) and
50% by weight of DIMSO Evol®
   (Solvent of type (S2)—commercial product as available from the company Arkema).

The mixture proves to be efficient for selectively stripping a film of photoresist after selective irradiation of only one part of its surface and leaving on the surface only the insoluble parts of the film.

1. A method, comprising stripping a photoresist using a mixture of solvents comprising at least two of the solvents (S1), (S2) and (S3) below:
(S1) a solvent comprising at least one esteramide compound corresponding to formula (I) below:
R¹OOC-A-CONR²R³ (I)
wherein:
R¹ is a group selected from saturated or unsaturated, linear or branched, optionally cyclic, optionally aromatic, hydrocarbon-based groups comprising an average number of carbon atoms ranging from 1 to 36,
R² and R³, which may be identical or different, are groups selected from saturated or unsaturated, linear or branched, optionally cyclic, optionally aromatic, optionally substituted, hydrocarbon-based groups comprising an average number of carbon atoms ranging from 1 to 36, R² and R³ together optionally being able to form a ring, which is optionally substituted and/or optionally comprises a heteroatom, and
A is a linear or branched divalent alkyl group comprising an average number of carbon atoms ranging from 2 to 12,
(S2) dimethyl sulfoxide DMSO
(S3) cyclopentanone C₅H₈O.

2. The method claimed in claim 1, wherein the mixture of solvents comprises a mixture of the solvent (S1) and of the solvent (S2).

3. The method claimed in claim 2, wherein the S1/S2 weight ratio of the weight of the solvent (S1) relative to the weight of the solvent (S2) is greater than or equal to 1.

4. The method claimed in claim 2, wherein the S1/S2 weight ratio of the weight of the solvent (S1) relative to the weight of the solvent (S2) is less than or equal to 1.

5. The method claimed in claim 1, wherein the mixture of solvents comprises a mixture of the solvent (S1) and of the solvent (S3).

6. The method claimed in claim 5, wherein the S1/S3 weight ratio of the weight of the solvent (S1) relative to the weight of the solvent (S3) is between 1 and 20.

7. The method claimed in claim 1, wherein the mixture of solvents comprises a mixture of the solvent (S2) and of the solvent (S3).

8. The method claimed in claim 1, wherein the mixture of solvents comprises a mixture of the solvent (S1), of the solvent (S2) and of the solvent (S3).

9. The method claimed in claim 1, wherein the S3/(S1+S2) weight ratio is less than 10%.

10. A process for selective depositing of a coating on certain zones only of the surface of a substrate, comprising:
(a) depositing of a film of photoresist on said surface; then
(b) selective irradiation of said film on certain zones only; then
(c) stripping of said film with a stripping solvent,
wherein said stripping solvent is a mixture of solvents comprising at least two of the solvents (S1), (S2) and (S3) below:
(S1) a solvent comprising at least one esteramide compound corresponding to formula (I) below:
R¹OOC-A-CONR²R³ (I)
wherein:
R¹ is a group selected from saturated or unsaturated, linear or branched, optionally cyclic, optionally aromatic, hydrocarbon-based groups comprising an average number of carbon atoms ranging from 1 to 36,
R² and R³, which may be identical or different, are groups selected from saturated or unsaturated, linear or branched, optionally cyclic, optionally aromatic, optionally substituted, hydrocarbon-based groups comprising an average number of carbon atoms ranging from 1 to 36, R² and R³ together optionally being able to form a ring, which is optionally substituted and/or optionally comprises a heteroatom, and
A is a linear or branched divalent alkyl group comprising an average number of carbon atoms ranging from 2 to 12,
(S2) dimethyl sulfoxide DMSO
(S3) cyclopentanone C₅H₈O.

11. The method claimed in claim 1, wherein A is a linear or branched divalent alkyl group comprising an average number of carbon atoms ranging from 2 to 4.

12. The method claimed in claim 2, wherein the mixture of solvents consists of a mixture of the solvent (S1) and of the solvent (S2).

13. The method claimed in claim 5, wherein the mixture of solvents consists of a mixture of the solvent (S1) and of the solvent (S3).

14. The method claimed in claim 7, wherein the mixture of solvents consists of a mixture of the solvent (S2) and of the solvent (S3).

15. The method claimed in claim 8, wherein the mixture of solvents consists of a mixture of the solvent (S1), of the solvent (S2) and of the solvent (S3).

16. The method claimed in claim 9, wherein the S3/(S1+S2) weight ratio is between 2% and 7%.
